(19) United States
(12) Patent Application Publication
(10) Pub. No.: US 2026/0013264 A1
(43) Pub. Date: Jan. 8, 2026

(54) AN OPTICAL MEDIA, METHOD OF MAKING AN OPTICAL MEDIA AND A PHOTOVOLTAIC WINDOW

(71) Applicant: NATIONAL UNIVERSITY OF SINGAPORE, Singapore (SG)

(72) Inventors: Yin Chiang BOEY, Singapore (SG); Chin Foo GOH, Singapore (SG); Shuhua LIU, Singapore (SG); Andy LI, Singapore (SG)

(21) Appl. No.: 19/111,834

(22) PCT Filed: Sep. 15, 2023
(86) PCT No.: PCT/SG2023/050626

§ 371 Date: Mar. 14, 2025

(30) Foreign Application Priority Data
Sep. 16, 2022 (SG) 10202251028U
Nov. 29, 2022 (CN) 202211506819.6

(51) Int. Cl. H10F 77/45; C09K 11/02; E06B 9/24; H02S 20/26; H02S 40/20

(52) U.S. Cl. CPC H10F 77/45; C09K 11/02; E06B 9/24; H02S 20/26; H02S 40/20; E06B 2009/2476

(57) ABSTRACT

Disclosed herein an optical media, a method of making an optical media and a photovoltaic window. The optical media includes a matrix and luminescent phosphors dispersed in the matrix. The luminescent phosphors include at least one of luminescent inorganic phosphors and quantum dot nanocrystals. The optical media may be made into a thin film attached to a window glass. The luminescent phosphors emit excitation light under irradiation of the incident light, which is converted into electrical energy through the photovoltaic cells. The photovoltaic window includes a light-transmitting substrate, an optical media and a first photovoltaic cell. The optical media is attached to the front/rear main surface of the light-transmitting substrate. The first photovoltaic cell is attached to the side surface of the light-transmitting substrate. The optical media receives the incident light projected on the light-transmitting substrate and generates excitation light which is projected on the first photovoltaic cell and converted into electrical energy.

### CROSS-REFERENCE TO RELATED APPLICATION

This application claims the benefit of priority to the Singapore application Ser. No. 10/202,251028U filed Sep. 16, 2022, and the China application no. 202211506819.6 filed Nov. 29, 2022, and the contents of which are hereby incorporated by reference in their entirety for all purposes.

### TECHNICAL FIELD

The application relates to the photovoltaic field, in particular to an optical media, a method of making an optical media, and a photovoltaic window.

### BACKGROUND

As a clean and renewable energy source, solar energy is increasingly receiving more attention. As a photovoltaic device that can be integrated into buildings or other facilities, photovoltaic windows convert a part of solar radiation into electrical energy through photovoltaic action, while retaining the lighting function of the window itself. However, there remain challenges for photovoltaic windows. For example, its low energy conversion efficiency and low visible light transmittance restrict its practical application.

### SUMMARY

In one aspect, the present application discloses an optical media, which includes a matrix and luminescent phosphors dispersed in the matrix. The luminescent phosphors include at least one of luminescent inorganic phosphors and quantum dot nanocrystals. The luminescent phosphors emit excitation light in multiple directions responsive to irradiation of incident light, which is used to convert the excitation light into electrical energy through photovoltaic cells.

In another aspect, the present application discloses a method of making an optical media. The method comprises making a solution of a matrix precursor and adding luminescent phosphors to the solution of the matrix precursor to obtain a solution of an optical media precursor. The solution of the optical media precursor has luminescent phosphors dispersed therein. The solution of the optical media precursor is cured to obtain an optical media which has a matrix and the luminescent phosphors dispersed in the matrix. The luminescent phosphors include at least one of luminescent inorganic phosphors and quantum dot nanocrystals.

In another aspect, the present application discloses a photovoltaic window. The photovoltaic window includes a light-transmitting substrate, an optical media and a first photovoltaic cell. The light-transmitting substrate has a front main surface; a rear main surface opposite to the front main surface; and a side surface laterally bridging the front main surface and the rear main surface. The optical media has a main plane attached conforming to at least one of the front surface and the rear surface of the light-transmitting substrate. The first photovoltaic cell has a main plane facing and attached abutting against the side surface of the light-transmitting substrate. The optical media includes a matrix and luminescent phosphors dispersed in the matrix. The luminescent phosphors include at least one of luminescent inorganic phosphors and quantum dot nanocrystals. Responsive to irradiation of an incident light projected on the light-transmitting substrate, the luminescent phosphors emit excitation light. The excitation light is projected on the first photovoltaic cell to convert the excitation light into electrical energy through the first photovoltaic cell.

In some embodiments, the photovoltaic window further comprises a second photovoltaic cell. The main plane of the second photovoltaic cell faces and is attached abutting the rear main surface of the light-transmitting substrate. The excitation light is projected on the second photovoltaic cell which is disposed on the rear main surface, to convert the excitation light into electrical energy through the second photovoltaic cell.

### BRIEF DESCRIPTION OF THE DRAWINGS

Various embodiments of the present disclosure are described below with reference to the following drawings:

FIG. 1 is a flowchart of a method of making an optical media according to an embodiment of the present disclosure;

FIG. 2 is a perspective view and a partial enlarged view of a photovoltaic window according to an embodiment of the present disclosure, in which a main plane of a photovoltaic cell faces a side surface of the photovoltaic window and is attached abutting the side surface of the photovoltaic window;

FIG. 3 is a partially exploded perspective view of the photovoltaic window as illustrated in FIG. 2;

FIG. 4 is a partially exploded perspective view of a photovoltaic window according to another embodiment of the present disclosure, in which a main plane of a photovoltaic cell faces a side surface and a rear main surface of the photovoltaic window respectively, and is attached abutting the side surface and the rear main surface of the photovoltaic window respectively; and

FIG. 5 is a schematic perspective view of the photovoltaic window as illustrated in FIG. 4, a photovoltaic cell with a main plane facing the side surface of the photovoltaic window and is attached abutting the side surface of the photovoltaic window is hidden, for the sake of brevity.

### DETAILED DESCRIPTION

The following detailed description is made with reference to the accompanying drawings, showing details and embodiments of the present disclosure for the purposes of illustration. Features that are described in the context of an embodiment may correspondingly be applicable to the same or similar features in the other embodiments, even if not explicitly described in these other embodiments. Additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance as generally understood in the relevant technical field, e.g., within 10% of the specified value.

As used herein, the term “and/or” includes any and all combinations of one or more of the associated listed items.

As used herein, “comprising” means including, but not limited to, whatever follows the word “comprising”. Thus, use of the term “comprising” indicates that the listed elements are required or mandatory, but that other elements are optional and may or may not be present.

As used herein, “consisting of” means including, and limited to, whatever follows the phrase “consisting of”. Thus, use of the phrase “consisting of” indicates that the listed elements are required or mandatory, and that no other elements may be present.

In one aspect, the present disclosure provides an optical media which includes a matrix and luminescent phosphors dispersed in the matrix. In some embodiments, the luminescent phosphors include at least one of luminescent inorganic phosphors and quantum dot nanocrystals. A mass fraction of the luminescent phosphors in the optical media may be in a range of 0.1% to 10%. The luminescent phosphors may have multiple emission peaks which correspond to light wavelengths in the range of 590 nanometers to 1200 nanometers. For example, luminescent inorganic phosphors may have emission peaks corresponding to light wavelengths around 910 nanometres and/or 1070 nanometres. Preferably, the luminescent phosphors have a first emission peak and a second emission peak, the first emission peak and the second emission peak corresponding to incident light having a light wavelength in the range of 800 nanometres to 1100 nanometres. The quantum dot nanocrystals may have emission peaks corresponding to light wavelengths around 600 nanometres and/or 630 nanometres. The luminescent inorganic phosphors may comprise at least one of luminescent red rare earth-doped phosphors and near infrared rare earth-doped phosphors, such as Y₂O₃, Y₂O₂S, YVO₄, CaMoO₄, Ca₉Al(PO₄)₇, CaTiO₃, MgSiO₃, CdSiO₃, Sr₂MgSi₂O₇, Mg₂SiO₄, CaO, SrO, BaO, Zn₃(PO₄)₂, SrAl₂O₄, LaGaO₃, La₃Ga₅GeO₁₄, ScBO₃, La₂MgZrO₆, La₃ScGa₃O₁₂, Y₃Sc₂Ga₃O₁₂, Gd₃Sc₂Ga₃O₁₂, Lu₃Sc₂Ga₃O₁₂, Y₃Ga₅O₁₂, Gd₃SC₂Ga₃O₁₂, ZnMoO₄, CaCuSi₄O₁₀, BaCuSi₄O₁₀, wherein the doped rare earth elements may be neodymium (Nd), dysprosium (Dy), holmium (Ho), erbium (Er), thulium (Tm), europium (Eu), terbium (Tb), etc. The mass fraction of the rare earth elements in the luminescent red rare earth-doped phosphors or mass fraction of the rare earth elements in the near infrared rare earth-doped phosphors may be in the range of 0.01% to 10%. In one example, the luminescent inorganic phosphors may have emission peaks corresponding to light wavelengths around 910 nanometres and/or around 1070 nanometres. Alternatively, in order to have a good or uniform dispersion in the matrix, the luminescent inorganic phosphor may include at least one of surface-treated luminescent red rare earth-doped phosphors and surface-treated near infrared rare earth-doped phosphors.

Quantum dot nanocrystals may include semiconducting metal chalcogenide quantum dot nanocrystals, such as one of or a combination of the following materials: CdS, CdSe, CdTe, PbS, PbSe, PbTe, ZnS, ZnSe, ZnTe, InP, InAs, CuzS, In₂S₃, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdS Se, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, AgIn(Se,S)₂, CuInS₂/ZnS, CuInSe₂/ZnS, etc. The quantum dot nanocrystals may have emission peaks corresponding to light wavelengths around 600 nanometres, around 630 nanometres and/or around 850 nanometres.

The matrix may be transparent or transmittable by an incident light which has a wavelength between 300 nanometres and 1000 nanometres. The matrix may be made of an epoxy resin, such as bisphenol-A-diglycidyl-ether (BADGE). Alternatively, the matrix may be made of methyl methacrylate (PMMA), carbonate, lauryl methacrylate (LMA), 2-hydroxyethyl methacrylate (HEMA), ethylene glycol dimethacrylate (EGDM), polydimethylsiloxane, polyethylene, polyacrylate, polysiloxane, polyacrylamide, polyimide, polyvinyl alcohol, polylactic acid, cellulose, polyvinylpyrrolidone, epoxy resin or a mixture thereof. The concentration of the quantum dots and the phosphors in the matrix may each be 0.2 percentage weight (wt %) respectively.

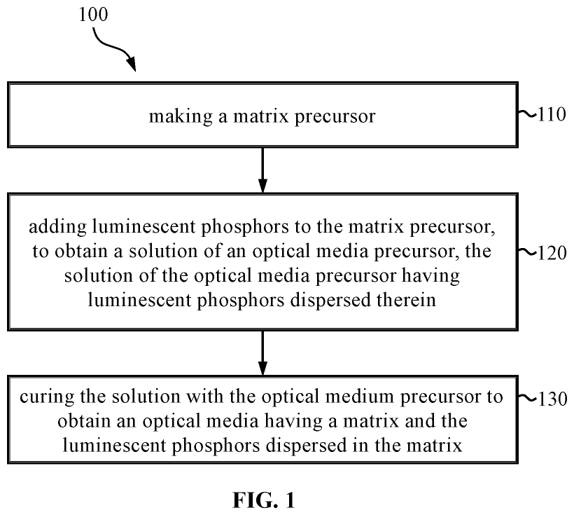

As shown in FIG. 1, a method 100 of making an optical media according to an embodiment is disclosed. The method 100 of making the optical media includes, at step 110, making a matrix precursor. For example, mixing 10 grams of transparent epoxy AB glue and 10 grams of hardener to make the matrix precursor. In some embodiments, the method 100 further includes making a solution of the matrix precursor.

In step 120, adding luminescent phosphors to the matrix precursor or the solution of the matrix precursor, to obtain a solution of an optical media precursor which is doped with the luminescent phosphors. For example, adding 20 milligrams of quantum dot powder with emission peaks of around 600 nanometres, 630 nanometres and/or 850 nanometres, and/or adding inorganic phosphors powder with emission peaks of around 910 nanometers and/or 1070 nanometers to 2 millilitres of toluene, to make a quantum dot suspension. The quantum dots may be made from one of or a combination of the following materials: CdS, CdSe, CdTe, PbS, PbSe, PbTe, ZnS, ZnSe, ZnTe, InP, InAs, CuzS, In₂S₃, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdS Se, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, AgIn(Se,S)₂, CuInS₂/ZnS, CuInSe₂/ZnS, etc. The inorganic phosphors may be made from one of or a combination of the following materials: Y₂O₃, Y₂O₂S, YVO₄, CaMoO₄, Ca₉Al(PO₄)₇, CaTiO₃, MgSiO₃, CdSiO₃, Sr₂MgSi₂O₇, Mg₂SiO₄, CaO, SrO, BaO, Zn₃(PO₄)₂, SrAl₂O₄, LaGaO₃, La₃Ga₅GeO₁₄, ScBO₃, La₂MgZrO₆, La₃ScGa₃O₁₂, Y₃Sc₂Ga₃O₁₂, Gd₃Sc₂Ga₃O₁₂, Lu₃Sc₂Ga₃O₁₂, Y₃Ga₅O₁₂, Gd₃Sc₂Ga₃O₁₂, ZnMoO₄, CaCuSi₄O₁₀, BaCuSi₄O₁₀ etc. The suspension containing quantum dots may be added to the matrix precursor dropwise, and thereafter sequentially adding inorganic phosphor powders with emission peaks corresponding to light wavelengths around 910 nanometres and 20 milligrams of inorganic phosphors powders with emission peaks at light wavelengths around 1070 nanometres, so as to obtain a solution of optical media precursor, in which the luminescent phosphors made of quantum dot/inorganic phosphor powder are dispersed.

In step 130, curing the solution of the optical media to obtain an optical media having a matrix and the luminescent phosphors dispersed in the matrix. The optical media may be made into an optical dielectric film, an optical dielectric plate or other optical structures. For example, the solution of the optical media precursor may be disposed on a polyethylene terephthalate (PET) sheet, this is followed by coating the PET sheet with the solution of the optical media precursor evenly with a film applicator, thereafter allowing 12 hours to 24 hours of static drying, to obtain an optical media, wherein the optical media has luminescent phosphors dispersed in the matrix. The luminescent phosphors in the optical media may be the quantum dot nanocrystals and/or phosphors as described in step 120, both of which have high photostability. In addition, the quantum dot nanocrystals have a relatively wide absorption band, while the phosphors have a relatively narrow line emission and a relatively large Stokes shift. The optical media as obtained has a relatively high photoelectric conversion efficiency.

In order to achieve better dispersion of the luminescent inorganic phosphors in the matrix, a ball milling process may be employed to reduce the average particle size of the inorganic phosphor powder, from an average particle size of greater than 5 micrometres to an average particle size of less than 2 micrometres. As the particle size or average particle size decreases, the degree of agglomeration of the inorganic phosphors powder decreases accordingly. The average size and distribution of particles before and after ball milling may be measured, for example, by a light scattering instrument. A non-limiting example of the ball milling process is as follows: by using a high-energy mechanical ball mill (HEMM, Fritsch Planetary Micro Mill Pulverisette 7 premium line), the inorganic phosphors were mixed with deionized water, zirconia microspheres with a diameter of 3 millimetres were used for ball milling at a speed of 1000 revolutions per minute (rpm). The ball milling process is operated over an extended duration, for example two hours, to obtain inorganic phosphors powder particles with smaller particle size.

The above operation of obtaining smaller particle sizes allows or enables the quantum dot nanocrystals or inorganic phosphors to be more uniformly distributed in the optical media. In some embodiments, the optical media may be a waveguide material. In these embodiments, luminescent quantum dot nanocrystals dispersed in the waveguide material with respective 600 nanometres and 630 nanometres emission peaks may be inspected using Ultra Violet light to determine the uniformity of the dispersion of the luminescent quantum dot nanocrystals. Inorganic phosphors dispersed in the waveguide material with respective 850 nanometres and 1070 nanometres emission peaks may be inspected using a short-wavelength infrared camera to determine the uniformity of the dispersion of the inorganic phosphors.

In another aspect, according to an embodiment, a photovoltaic window with an attached optical media, such as a flexible optical dielectric film optical media attached thereto, is disclosed. The photovoltaic window may include a light-transmitting substrate, a first photovoltaic cell and an optical media. The light-transmitting substrate includes a front main surface, a rear main surface opposite to the front main surface, and a side surface laterally bridging or laterally connecting the front main surface and the rear main surface transversely. The main plane of the first photovoltaic cell faces the side surface of the light-transmitting substrate and is attached abutting the side surface of the light-transmitting substrate. The optical media has a main plane attached conforming to at least one of the front main surface and the rear main surface of the light-transmitting substrate. The light-transmitting substrate may be a glass substrate, such as a low-iron glass substrate. As non-limiting examples, the first photovoltaic cell may be a crystalline silicon photovoltaic cell, a copper indium gallium selenide photovoltaic cell, or the like. The optical media includes a matrix and luminescent phosphors dispersed in the matrix. The luminescent phosphors include at least one of luminescent inorganic phosphors and quantum dot nanocrystals. The luminescent phosphors in the optical media have a mass fraction in the range of 0.1% to 10%. The luminescent inorganic phosphors have emission peaks corresponding to light wavelengths of around 910 nanometres and/or 1070 nanometres. The quantum dot nanocrystals have emission peaks corresponding to light wavelengths of around 600 nanometers and/or 630 nanometers. The quantum dot nanocrystals, phosphors and matrices can be arranged as described above for the optical media. The concentrations of the quantum dot nanocrystals and the phosphor in the matrix may each be 0.2 percentage weight (wt %) respectively. With reference to FIG. 1, the optical media may be made according to the method 100 as described above.

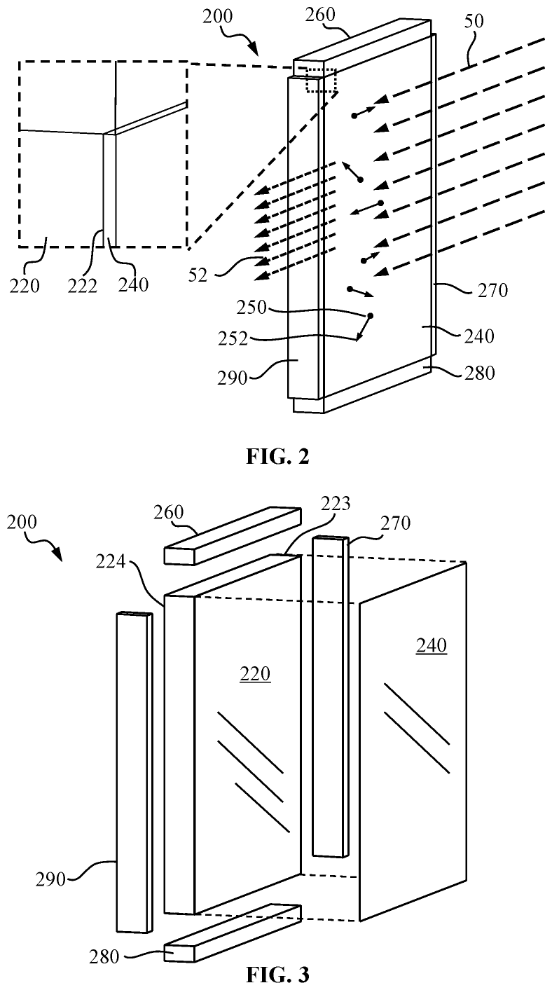

As illustrated in FIGS. 2 and 3, a photovoltaic window 200 according to an embodiment of the present disclosure includes a light-transmitting substrate 220, first photovoltaic cells 260/270/280/290, and an optical media 240. The light-transmitting substrate 220 includes a front main surface 222, a rear main surface 224 opposite to the front main surface 222, and a side surface 223 laterally bridging or laterally connecting the front main surface 222 and the rear main surface 224. The photovoltaic window 200 may be positioned with the front main surface 222 facing the direction of the incident light 50. The incident light 50 may be sunlight, light from a bulb/lamp, or the like. The main plane of each first photovoltaic cell 260/270/280/290 faces and is attached abutting the respective side surfaces 223 of the light-transmitting substrate 220. The first photovoltaic cells 260/270/280/290 may be crystalline silicon photovoltaic cells and may be connected to each other in series. The main plane of the optical media 240 faces and is attached conforming to the front main surface 222 of the photovoltaic window 200. The light-transmitting substrate 220 may be a low-iron glass substrate. According to a specific example, the photovoltaic window 200 has a length of 30 centimetres and a width of 30 centimetres. While the incident light 50 passes through the light-transmitting substrate 220 as transmitted light 52, the luminescent inorganic phosphors and/or quantum dot nanocrystals 250 doped in the optical media 240 convert the incident light 50 into excitation light 252. The excitation light 252 is emitted towards multiple different directions relative to the light-transmitting substrate 220 in a scattered manner, and a part of the excitation light is projected on the first photovoltaic cells 260/270/280/290 and converted into electrical energy. The photovoltaic window as described in the specific example can produce a maximum open circuit voltage of 74 volts, a maximum short circuit current of 37 mA, a photoelectric conversion efficiency (PCE) of 3.0% to 3.5%, and a power generation of 30.4 watts/square meter.

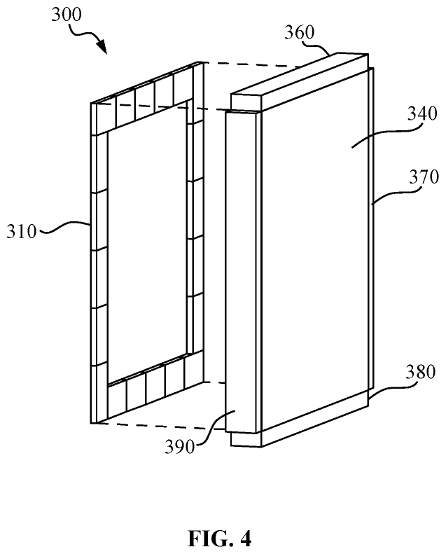

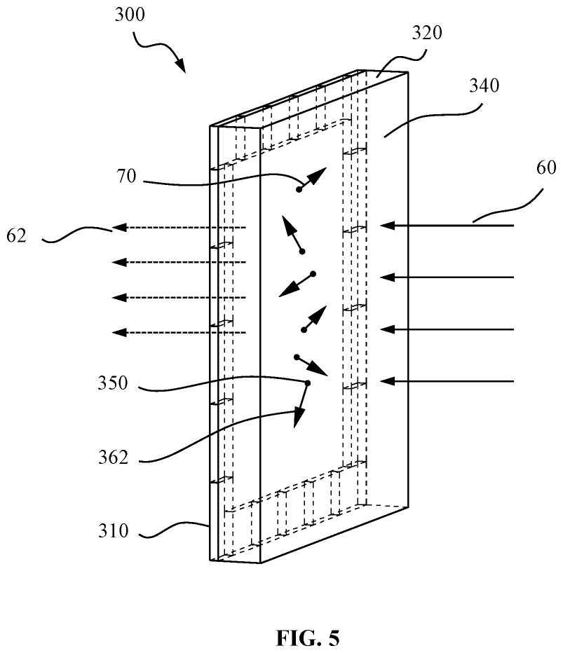

According to another embodiment, as shown in FIG. 4 and FIG. 5, the photovoltaic window 300 includes a light-transmitting substrate 320, first photovoltaic cells 360/370/380/390, and an optical medium 340. The light-transmitting substrate 320 has a front main surface, a rear main surface opposite to the front main surface, and a side surface laterally bridging the front main surface and the rear main surface. The front main surface faces the incident light 60, wherein the incident light 60 may be sunlight, light from a lamp/bulb, etc. Although the incident light 60 is shown as entering the light-transmitting substrate 320 in a vertical direction, it is understood that the incident light 60 may enter the light-transmitting substrate 320 at any angle. The incident light 60 may also enter the light-transmitting substrate 320 with one or multiple angles. The main plane of each first photovoltaic cell 360/370/380/390 faces and is attached abutting the respective side surfaces of the light-transmitting substrate 320. The main plane of the optical media 340, which may be fabricated according to the method 100 described above with respect to FIG. 1, faces and is attached abutting the front main surface of the photovoltaic window 300. The photovoltaic window 300 may also include a plurality of second photovoltaic cells 310, each second photovoltaic cell 310 includes a main plane which faces and is attached abutting the rear main surface of the photovoltaic window 300. In some embodiments, the second photovoltaic cells 310 may be disposed or positioned on a periphery of the rear main surface. The photovoltaic cells 310/360/370/380/390 may be connected in series. The photovoltaic cells 310/360/370/380/390 may receive/harvest energy from transmitted light 262 and the scattered light formed in the light-transmitting substrate 320 and optical media 340 responsive to the incident light 60 passing through, as well as receive/harvest energy from the excitation light 362 emitted by the optical media 340 which includes luminescent inorganic phosphors and/or quantum dot nanocrystals 350, responsive to absorbing the incident light 60. In comparison to the first photovoltaic cells 360/370/380/390, the second photovoltaic cells 310 are able to collect more energy from the transmitted light 62 and scattered light, and the photovoltaic cells 310 thereby improves the energy collection efficiency of the photovoltaic window 300. The photovoltaic cells 310/360/370/380/390 may be crystalline silicon photovoltaic cells. The light-transmitting substrate 320 may be a low-iron glass substrate. The photovoltaic window 300 has high light transmittance, high energy harvesting efficiency, wide absorption band from ultraviolet light to visible light to near infrared light, and has good performance when exposed to radiation, moisture/humidity, heat, oxygen, etc. long-term stability.

### Example 1

In the present example, orange-emissive quantum dot powder and near-infrared quantum dot powder are used, with the emission peak of the orange-emissive quantum dot powder around 600 nanometres, and the emission peak of the near-infrared emitting quantum dot powder around 850 nanometres. Specifically, 20 milligrams of orange-emissive quantum dot powder and 20 milligrams of near-infrared quantum dot powder are dispersed in 2 millilitres of toluene to form a suspension. To prevent particle agglomeration, the suspension is homogenized by ultrasonication for 5 min. For the purpose of compensating for the volatilization loss of toluene, toluene may also be added to the suspension to keep the total volume of the suspension at 2 millilitres.

A transparent epoxy resin AB glue (comprising a component of epoxy resin agent and a component of hardener) may be used as the matrix to receive the quantum dots that are mixed in the matrix. The epoxy resin agent and hardener in the transparent epoxy resin AB glue may weigh 10 grams each. In the epoxy resin AB glue, the concentration of quantum dots is around 0.2 percentage weight (wt %). The optical media made according to the above concentration can generate relatively abundant excitation light and scattered light under sunlight irradiation, and at the same time, maintain a high light transmittance in the glass window panel.

The epoxy resin agent and the hardener are fully mixed by mechanical stirring. The toluene suspension of quantum dots may be added dropwise to the epoxy resin agent and hardener mixture, and the mixture is stirred for 30 minutes prior to transferring the mixture to a beaker. The mixture is poured and spread onto a transparent polyethylene terephthalate (PET) sheet with a size of 30 centimetres by 30 centimetres and a visible light transmittance of 90%. Thereafter, a film applicator (5 centimetres in width and 50 micrometres in film thickness) is used to form a quantum dots/epoxy luminescent film on the PET sheet. After the film is dried in a fume hood for 12 hours to 24 hours, the film is attached to a low-iron glass panel (30 centimetres by 30 centimetres by 1.5 centimetres) using an adhesive suitable for bonding PET. Thereafter, using a transparent resin, 12 crystalline silicon photovoltaic cells (with a size of 10 centimetres by 2.8 centimetres) connected in series are attached to or adhered to the four side surfaces of the glass panel, thus completing the assembly of the luminous solar energy harvesting glass window panel or photovoltaic window.

### Example 2

In another example, red-emissive quantum dot nanocrystals and two types of near-infrared emitting inorganic phosphor powders are used, with the emission peaks of the two types of inorganic phosphors corresponding to light wavelengths of 910 nanometres and 1070 nanometres respectively. Both types of phosphor powders may be ball milled to minimize particle agglomeration and to minimize particle size for better dispersion of the phosphor powders in an epoxy matrix. The quantum dot/phosphor concentration in the epoxy is kept at 0.2 percentage weight (wt %). The optical media made according to the concentration setting can generate relatively abundant excitation light and scattered light under sunlight irradiation, and at the same time, maintain a high light transmittance in the glass window panel.

According to a specific example, 20 milligrams of red-emissive quantum dots are dispersed in 2 milliliters of toluene to form a suspension; at the same time, 10 milligrams of phosphor powders with emission peaks around the light wavelength of 910 nanometers and 10 milligrams of phosphor powders with emission peaks around the light wavelength of 1070 nanometers are mixed in the toluene forming a suspension. The suspension may be homogenized by ultrasonication for 5 minutes during the dispersing of the red-emissive quantum dots. To compensate for the volatilization loss of toluene, toluene may be added to the suspension to keep the total volume at 2 millilitres. A transparent epoxy resin AB glue, which includes 10 grams of epoxy resin agent and 10 grams of hardener, may be used to mix quantum dots into the phosphor matrix. Mechanical stirring is used to fully mix the epoxy resin agent and the hardener. Under mechanical stirring, the quantum dot-toluene suspension is added dropwise to the mixture of the epoxy resin agent and the hardener. Thereafter, phosphor powder with emission peak corresponding to light wave wavelength of 910 nanometers and phosphor powder with mission peak corresponding to light wave wavelength of 1070 nanometers are added to the mixture. The epoxy resin, quantum dots, and phosphor powders are stirred and mixed for half an hour prior to the mixture being transferred to a beaker. Thereafter, the mixture is then poured and spread onto a 30 centimetres by 30 centimetres transparent PET sheet (90% visible light transmittance). A film applicator (5 centimetres in width and 50 micrometres in film thickness) is used to make a quantum dot-phosphor epoxy film on the PET sheet. After the film is dried in a fume hood for 12 hours to 24 hours, the film is attached to or adhered to a low-iron glass panel (30 centimetres by 30 centimetres by 1.5 centimetres) using an adhesive suitable for bonding PET. Thereafter, using a transparent resin, 20 crystalline silicon photovoltaic cells (5.3 centimetres by 3.0 centimetres) are attached to or adhered to the rear main plane of the glass panel, which faces the incident direction of sunlight, so as to complete the assembly of the luminous sunlight energy harvesting glass window panel or photovoltaic window. Further, 12 crystalline silicon photovoltaic cells (9.0 centimetres by 3.0 centimetres) are attached to or adhered to the four side surfaces of the glass panel, facing the glass side surfaces. All of the 32 photovoltaic cells are connected in series with each other.

The test results show that under the same conditions of sunlight radiation, the photovoltaic window according to this example can produce a maximum open circuit voltage of 123.3 volts and a maximum short circuit current of 13.39 milliamperes. In comparison, the maximum open circuit voltage of a reference window panel is 122.0 volts, and the maximum short circuit current of the reference window panel is 8.67 milliamperes.

All examples described herein, whether of apparatus, methods, materials, or products, are presented for the purpose of illustration and to aid understanding, and are not intended to be limiting or exhaustive. Modifications may be made by one of ordinary skill in the art without departing from the scope of the invention as claimed.

1. An optical media, comprising:
a matrix; and
luminescent phosphors dispersed in the matrix, wherein the luminescent phosphors include at least one of luminescent inorganic phosphors and quantum dot nanocrystals,
wherein the luminescent phosphors emit excitation light responsive to irradiation of an incident light.

2. The optical media as recited in claim 1, wherein the luminescent inorganic phosphors have an average particle size below 2 micrometres.

3. The optical media as recited in claim 1, wherein the matrix is made from one or a combination of the following materials:
bisphenol A diglycidyl ether, methyl methacrylate, carbonate, lauryl methacrylate, 2-hydroxyethyl methacrylate, ethylene glycol dimethacrylate, dimethicone, polyethylene, polyacrylate, polysiloxane, polyacrylamide, polyimide, polyvinyl alcohol, polylactic acid, cellulose, polyvinylpyrrolidone, and epoxy resins.

4. The optical media as recited in claim 1, wherein the luminescent inorganic phosphors are made of one or a combination of the following materials:
Y₂O₃, Y₂O₂S, YVO₄, CaMoO₄, Ca₉Al(PO₄)₇, CaTiO₃, MgSiO₃, CdSiO₃, Sr₂MgSi₂O₇, Mg₂SiO₄, CaO, SrO, BaO, Zn₃(PO₄)₂, SrAl₂O₄, LaGaO₃, La₃Ga₅GeO₁₄, ScBO₃, La₂MgZrO₆, La₃ScGa₃O₁₂, Y₃Sc₂Ga₃O₁₂, Gd₃Sc₂Ga₃O₁₂, Lu₃Sc₂Ga₃O₁₂, Y₃Ga₅O₁₂, Gd₃Sc₂Ga₃O₁₂, ZnMoO₄, CaCuSi₄O₁₀, and BaCuSi₄O₁₀.

5. The optical media as recited in claim 4, wherein the luminescent inorganic phosphors comprise rare earth-doped phosphors, wherein the rare earth-doped phosphors include one or a combination of the following rare earth elements: neodymium, dysprosium, holmium, erbium, thulium, europium, terbium; and wherein a mass fraction of the rare earth elements in the rare earth-doped phosphors is in a range of 0.01% to 10%.

6. The optical media as recited in claim 1, wherein the quantum dot nanocrystal is made from one or a combination of the following materials:
CdS, CdSe, CdTe, PbS, PbSe, PbTe, ZnS, ZnSe, ZnTe, InP, InAs, CuzS, In₂S₃, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdS Se, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, AgIn(Se,S)₂, CuInS₂/ZnS, and CuInSe₂/ZnS.

7. The optical media as recited in claim 1, wherein the mass fraction of the luminescent phosphors in the optical media is in a range of 0.1% to 10%.

8. The optical media as recited in claim 1, wherein the luminescent phosphor includes a first emission peak and a second emission peak, the first emission peak and the second emission peak corresponding to a light wavelength of an incident light in a range of 590 nanometers to 1200 nanometers, wherein the first emission peak corresponds to a light wavelength of 600 nanometers, and the second emission peak corresponds to a light wavelength of 910 nanometers.

9. The optical media as recited in claim 8, wherein the luminescent phosphor includes a first emission peak and a second emission peak, the first emission peak and the second emission peak corresponding to a light wavelength in a range of 800 nanometers to 1100 nanometers of an incident light.

10. A method of making an optical media, wherein in that the method comprises:
making a solution of a matrix precursor;
adding luminescent phosphors to the solution of the matrix precursor to obtain a solution of an optical media precursor, the solution of the optical media precursor having the luminescent phosphors dispersed therein, wherein the luminescent phosphors include at least one of luminescent inorganic phosphors and quantum dot nanocrystals; and
curing the solution of the optical media precursor to obtain an optical media having a matrix and the luminescent phosphors dispersed in the matrix.

11. The method as recited in claim 10, further comprising reducing an average particle size of the luminescent inorganic phosphors before adding the luminescent phosphors into the solution of the matrix precursor.

12. The method as recited in claim 10, wherein the matrix precursor is made of one or a combination of the following materials:
bisphenol A diglycidyl ether, methyl methacrylate, carbonate, lauryl methacrylate, 2-hydroxyethyl methacrylate, ethylene glycol dimethacrylate, dimethicone, polyethylene, polyacrylate, polysiloxane, polyacrylamide, polyimide, polyvinyl alcohol, polylactic acid, cellulose, polyvinylpyrrolidone, and epoxy resin.

13. The method as recited in claim 10, wherein the luminescent inorganic phosphors are made of one or a combination of the following materials:
Y₂O₃, Y₂O₂S, YVO₄, CaMoO₄, Ca₉Al(PO₄)₇, CaTiO₃, MgSiO₃, CdSiO₃, Sr₂MgSi₂O₇, Mg₂SiO₄, CaO, SrO, BaO, Zn₃(PO₄)₂, SrAl₂O₄, LaGaO₃, La₃Ga₅GeO₁₄, ScBO₃, La₂MgZrO₆, La₃ScGa₃O₁₂, Y₃Sc₂Ga₃O₁₂, Gd₃Sc₂Ga₃O₁₂, Lu₃Sc₂Ga₃O₁₂, Y₃Ga₅O₁₂, Gd₃SC₂Ga₃O₁₂, ZnMoO₄, CaCuSi₄O₁₀, and BaCuSi₄O₁₀.

14. The method as recited in claim 13, wherein the luminescent inorganic phosphors comprise rare earth-doped phosphors, wherein the rare earth-doped phosphors include one or a combination of the following rare earth elements: neodymium, dysprosium, holmium, erbium, thulium, europium, terbium; and wherein the mass fraction of the rare earth elements in the rare earth-doped phosphors is in a range of 0.01% to 10%.

15. The method as recited in claim 10, wherein the quantum dot nanocrystals are made of one or a combination of the following materials:
CdS, CdSe, CdTe, PbS, PbSe, PbTe, ZnS, ZnSe, ZnTe, InP, InAs, CuzS, In₂S₃, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdS Se, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, AgIn(Se,S)₂, CuInS₂/ZnS, and CuInSe₂/ZnS.

16. The method as recited in claim 10, wherein the mass fraction of the luminescent phosphors in the optical media is in a range of 0.1% to 10%.

17. The method as recited in claim 10, wherein the luminescent phosphors include a first emission peak and a second emission peak, the first emission peak and the second emission peak corresponding to a light wavelength in a range of 590 nanometers to 1200 nanometers of an incident light, wherein the first emission peak corresponds to a light wavelength of 600 nanometers, and the second emission peak corresponds to a light wavelength of 910 nanometers.

18. The method as recited in claim 17, wherein the luminescent phosphors include a first emission peak and a second emission peak, the first emission peak and the second emission peak corresponding to a light wavelength in a range of 800 nanometers to 1100 nanometers of an incident light.

19. A photovoltaic window, comprising:
a light-transmitting substrate, the light-transmitting substrate having a front main surface; a rear main surface opposite to the front main surface; and a side surface laterally bridging the front main surface and the rear main surface;
an optical media, the optical media having a main plane attached conforming to at least one of: the front surface and the rear surface of the light-transmitting substrate;
a first photovoltaic cell, the first photovoltaic cell having a main plane facing and attached abutting against the side surface of the light-transmitting substrate;
wherein the optical media includes a matrix and luminescent phosphors dispersed in the matrix, wherein the luminescent phosphors include at least one o luminescent inorganic phosphors and quantum dot nanocrystals, and
wherein responsive to irradiation of an incident light projected on the light-transmitting substrate, the luminescent phosphors emit excitation light, wherein the excitation light projects on the first photovoltaic cell.

20. The photovoltaic window as recited in claim 19, further comprising a second photovoltaic cell, the second photovoltaic cell having a main plane facing and attached abutting against the rear main surface of the light-transmitting substrate, wherein the excitation light projects on the second photovoltaic cell disposed on the rear main surface.

21. The photovoltaic window as recited in claim 20, wherein the second photovoltaic cell is disposed on a periphery of the rear main surface.

22. The photovoltaic window as recited in claim 19, wherein the light-transmitting substrate is made of one or a combination of the following materials:
Bisphenol A Diglycidyl Ether, Methyl Methacrylate, Carbonate, Lauryl Methacrylate, 2-Hydroxyethyl Methacrylate, Ethylene Glycol Dimethacrylate, Dimethicone, Polyethylene, polyacrylate, polysiloxane, polyacrylamide, polyimide, polyvinyl alcohol, polylactic acid, cellulose, polyvinylpyrrolidone, and epoxy resin;
wherein the luminescent inorganic phosphors are made of one or a combination of the following materials:
Y₂O₃, Y₂O₂S, YVO₄, CaMoO₄, Ca₉Al(PO₄)₇, CaTiO₃, MgSiO₃, CdSiO₃, Sr₂MgSi₂O₇, Mg₂SiO₄, CaO, SrO, BaO, Zn₃(PO₄)₂, SrAl₂O₄, LaGaO₃, La₃Ga₅GeO₁₄, ScBO₃, La₂MgZrO₆, La₃ScGa₃O₁₂, Y₃Sc₂Ga₃O₁₂, Gd₃Sc₂Ga₃O₁₂, Lu₃Sc₂Ga₃O₁₂, Y₃Ga₅O₁₂, Gd₃Sc₂Ga₃O₁₂, ZnMoO₄, CaCuSi₄O₁₀, and BaCuSi₄O₁₀;
wherein the quantum dot nanocrystals are made of one or a combination of the following materials:
CdS, CdSe, CdTe, PbS, PbSe, PbTe, ZnS, ZnSe, ZnTe, InP, InAs, CuzS, In₂S₃, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdS Se, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, AgIn(Se,S)₂, CuInS₂/ZnS, and CuInSe₂/ZnS.

23. The photovoltaic window as recited in claim 22, wherein the luminescent inorganic phosphors comprise rare earth-doped phosphors, wherein the rare earth-doped phosphors include one or a combination of the following rare earth elements:
neodymium, dysprosium, holmium, erbium, thulium, europium, terbium; and wherein a mass fraction of the rare earth elements in the rare earth-doped phosphors is in a range of 0.01% to 10%.

24. The photovoltaic window as recited in claim 19, wherein the mass fraction of the luminescent phosphors in the optical media is in a range of 0.1% to 10%.

25. The photovoltaic window as recited in claim 19, wherein the luminescent phosphors include a first emission peak and a second emission peak, the first emission peak and the second emission peak having a light wavelength in a range of 590 nanometers to 1200 nanometers, wherein the first emission peak is a light wavelength of 600 nanometers, and the second emission peak is a light wavelength of 910 nanometers.

26. The photovoltaic window as recited in claim 25, wherein the luminescent phosphors include a first emission peak and a second emission peak, the first emission peak and the second emission peak corresponding to a light wavelength in a range of 800 nanometers to 1100 nanometers of an incident light.

27. The photovoltaic window as recited in claim 19, wherein the luminescent inorganic phosphors have an average particle size below 2 micrometres.
